(19) United States
(12) Patent Application Publication
(10) Pub. No.: US 2008/0246147 A1
(43) Pub. Date: Oct. 9, 2008

(54) Novel substrate design for semiconductor device

(76) Inventors: Chao-Yuan Su, Hsin-Chu County (TW); Chia Hsiung Hsu, Hsinchu City (TW); Steven Hsu, Chung-Ho City (TW)

Correspondence Address: SLATER & MATSIL, L.L.P., 17950 PRESTON ROAD, SUITE 1000, DALLAS, TX, 75252, US

(21) Appl. No.: 11/784,730

(22) Filed: Apr. 9, 2007

(51) Int. Cl. H01L 23/488; H01L 21/441; H01L 21/60

(52) U.S. Cl. 257/738; 438/108; 438/613; 257/E23.023; 257/E21.508; 257/E21.477

(57) ABSTRACT

A novel design and method of fabricating a semiconductor device. In a preferred embodiment, the present invention is a flip chip package including a BT substrate. On the side of the substrate facing the die, thin traces are formed of an enhanced conductive material. Conductive bumps such as eutectic solder balls are then mounted on the traces, and the die mounted to the bumps. The die then packaged and mounted to a printed circuit board using, for example, a ball grid array.

### TECHNICAL FIELD

The present invention relates generally to the field of semiconductor chip package design, and relates more particularly to a novel substrate design that is especially advantageous when implemented in a flip chip package.

### BACKGROUND

A flip chip is a type of semiconductor device. Semiconductor devices are very small electrical components interconnected into integrated circuits that perform various computing and memory functions necessary to the generation of modern electronic appliances. Appliances based on semiconductor devices include personal computers, mobile telephones, and personal entertainment devices, as well as many others. Not only are such appliances popular, but advances in materials, design, and fabrication technology have made them more affordable for the average consumer. This affordability has in turn enabled many additional applications for use of semiconductor devices and, of course, increased their popularity even more.

In general, semiconductor devices are fabricated by forming millions of tiny electronic components onto a thin slice of semiconducting material such as silicon. This slice of silicon, often called a wafer, may be treated with impurities to affect its electrical properties. Most significantly, silicon may be treated, or doped, in order to give it semiconducting properties. A semiconductor conducts electricity only under certain conditions, such as the application of electrical charge, enabling it to operate, for example, as a switch without the need for moving parts. A transistor is an example of just such a device. The transistor is formed by placing in proximity to the doped silicon, various small conducting and insulating component parts; these component parts are used to conduct and control the current flowing through the transistor.

Components such as transistors are formed on the wafer substrate by alternately depositing layers of conducting and insulating material, and selectively etching away portions of these layers to form the necessary component parts. The interconnections between these parts are similarly formed. A typical wafer is used as a substrate for forming a number, perhaps dozens of individual devices called dice. All of the dice on a wafer are typically, fabricated simultaneously and then separated for packaging and use.

Each die contains most or all of the electrical circuits needed to perform an intended function, and is typically sold as a discrete unit, although it is becoming increasingly common for two or more dice to be packaged and sold together (sometimes referred to as a hybrid chip). Prior to use, each individual die (or set of dice) are typically encapsulated, or packaged in a protective material. This protective material must securely hold the die and permit the passage of conductors for external electrical connections. To accomplish this, for example, a die may have a number of bond pads to which electrical connections may be made. Fine wires are bonded to the bond pads at one end and then to leads at the other. The leads extend beyond the protective package to connect to a printed circuit board or similar device. Generally, the die face having the electrical components formed on it faces up so these wire bond connections may be made. Face up in this sense means that the active surface of the die faces away from its mounting and electrical connection points.

A chip, or packaged die, that faces toward its mounting is for this reason often referred to as a flip chip. Although this orientation poses some challenges not present in more traditional structures. Flip chips are becoming popular because they can often be enclosed in a smaller package, which will in turn fit into a smaller device. One reason for this, and at the same time one of the challenges posed by this design, is that external connections to the die are not made with bond wires. In a flip chip, at least some if not all of these connections are made using small conductive objects, often referred to as bumps, or balls. This will be illustrated with reference to FIG. 1.

FIG. 1 is a side view illustrating in cross-section selected components of a typical flip chip semiconductor device 10. In the example of FIG. 1, flip chip 10 has a die 12 having an active surface 13. The active surface 13 of die 12 is one upon which the electrical components of the device have been fabricated. (Although not typical or shown here, electrical components may be fabricated on other areas of the die as well, creating more than one active surface.) As alluded to above, active surface 13 of flip chip 10 faces the substrate 15 on which the die 12 is mounted. Die 12 is mounted using an array of conductive bumps, five of which are visible in FIG. 1 and numbered 21 through 25. Conductive bumps 21 through 25, which in this example are solder balls, are arrayed so as to provide both structural and mechanical coupling to the active surface 13 of die 12 and face 16 of substrate 15. The point of contact with die active surface 13 or substrate face 16 is typically at a bond pad (not shown in FIG. 1) or similar structure designed for this purpose and laminated or otherwise attached to the respective surface. An intermediate structure sometimes referred to as UBM (under ball metallurgy) may be present as well. Note, however, that although only five solder balls performing their function are shown in FIG. 1, there are typically many more.

Die 12 and conductive bumps 21 through 25 are encased in an encapsulant 20, which provides the familiar appearance of the flip chip 10 and protects the internal components. Solder balls 31 through 37 are mounted on the outside face 17 of substrate 15 and provide a means to electrically and mechanically couple the flip chip 10 to a printed circuit board or similar mounting surface. Solder balls 31 through 37 are mounted on pads (not shown in FIG. 1) that are themselves coupled through vias (also not shown) in substrate 15 to conductive bumps 21 through 25 or other internal components. Note that FIG. 1 is a simplified representation of a flip chip, and typically many more internal components are present.

FIG. 2 is a plan view illustrating a portion of the internal pad array 40 of a typical substrate 15 in a flip chip semiconductor device such as the one shown in FIG. 1. Shown in FIG. 2 are seven electrical traces numbered 41 through 47. At the terminus of each trace is a pad, numbered 51 though 57 for mounting a conductive bump (Such as conductive bumps 21 through 25 shown in FIG. 1, thorough a direct correspondence is not intended). The pads are often located over vias (not shown) to achieve connections with features on the other side of substrate 15. In the example of FIG. 2, which is not a typical, the pads must be a certain minimum size to avoid delamination, and therefore frequently allow only one trace to escape (that is, be routed) between two adjacent pads.

This can also be seen in FIG. 3. FIG. 3 is a side view illustrating in cross-section a portion of the internal pad array 40 illustrated in FIG. 2, along with a portion of a die 12 mounted on the substrate 15, which supports the pad array. Here die 12 is mounted by conductive mounts with its active surface 13 facing substrate 15, as in FIG. 1, but in FIG. 3 the pads are also shown. As mentioned above, generally only a single trace may be routed in between the pads, limiting design options. The width of the pad is larger than the width of electrical trace. Due to design consideration, there is only one single trace available between two pads. Referring to the portion of flip chip 10 shown in FIG. 3, conductive bumps 23 and 25 are shown in position connected to active surface of die 12, and mounted on substrate 15 at pads 53 and 55, respectively. Electrical trace 44, disposed between the pads, is also visible. As should be apparent, however, where only one trace may be routed between the two pads, routing options are undesirably limited.

Needed, then, is a flip chip having a low-cost substrate solution that permits greater routability and is suitable for use with smaller conductive bumps arranged in a fine-pitch array. The present invention provides just such a solution.

### SUMMARY OF THE INVENTION

These and other problems are generally solved or circumvented, and technical advantages are generally achieved, by preferred embodiments of the present invention, which are directed to a flip-chip substrate design, and in particular to a flip chip having a BT (bismalelemide triazine) laminate substrate. This invention may be of particular advantage in a hybrid package including multiple dice especially when a very fine pitch bump array is implemented. Use of the present invention in other embodiments, however, may be directed to other applications.

In one aspect, the present invention is a semiconductor device having a die mounted on a substrate by a plurality of conductive bumps that also provide an electrical connection between integrated circuits formed on the die and thin electrical traces formed on the substrate, to which the conductive bumps are mounted. The mounted die may then be encapsulated and coupled to a printed circuit board for use in an electronic appliance.

In another aspect, the present invention is a method of fabricating a semiconductor device, including forming a thin conductive layer on a substrate, patterning the thin conductive layer to form a plurality of traces, enhancing the traces with additional conductive material, and mounting conductive bumps onto the traces. The method further includes mounting a die onto the conductive bumps, and enclosing the die in packaging material. Dependent claims further describe the invention by requiring that the conductive traces be formed of or enhanced with copper. In a preferred embodiment, the substrate is a BT laminate and the conductive layer is formed using a plasma or surface-treatment process. In any case, solder balls may then be mounted on the substrate opposite the mounted die, and the chip may be mounted in an electronic appliance.

An advantage of a preferred embodiment of the present invention is that a low-cost soulution is presented for securely mounting relatively small conductive bumps such as solder balls that must be placed in a fine-pitch array.

A further advantage of a preferred embodiment of the present invention is that it enhances routability of electrical traces on the substrate by permitting multiple traces to escape between two adjacent conductive bumps.

A more complete appreciation of the present invention and the scope thereof can be obtained from the accompanying drawings that are briefly summarized below, the following detailed description of the presently-preferred embodiments of the present invention, and the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is a side (elevation) view illustrating in cross-section selected components of a typical flip chip semiconductor device.

FIG. 2 is a plan view illustrating a portion of the pad array of a typical substrate in a flip chip semiconductor device such as the substrate illustrated in FIG. 1.

FIG. 3 is a side view illustrating in cross-section a portion of the pad array shown in FIG. 2 and a mounted die.

FIG. 4 is a side view illustrating in cross-section a portion of a flip chip according to an embodiment of the present invention.

FIG. 5 is a plan view illustrating a portion of the trace pattern on a substrate according to an embodiment of the present invention.

FIG. 6 is a flow diagram, illustrating a method of fabricating a semiconductor device according to an embodiment of the present invention.

FIGS. 7a through 7k are a sequence of side views illustrating in cross-section the configuration of a semiconductor device during fabrication according to a method of the present invention.

FIG. 8 is a plan view illustrating a partial trace pattern 809 on the surface 806 of a substrate 805 according to an embodiment of the present invention.

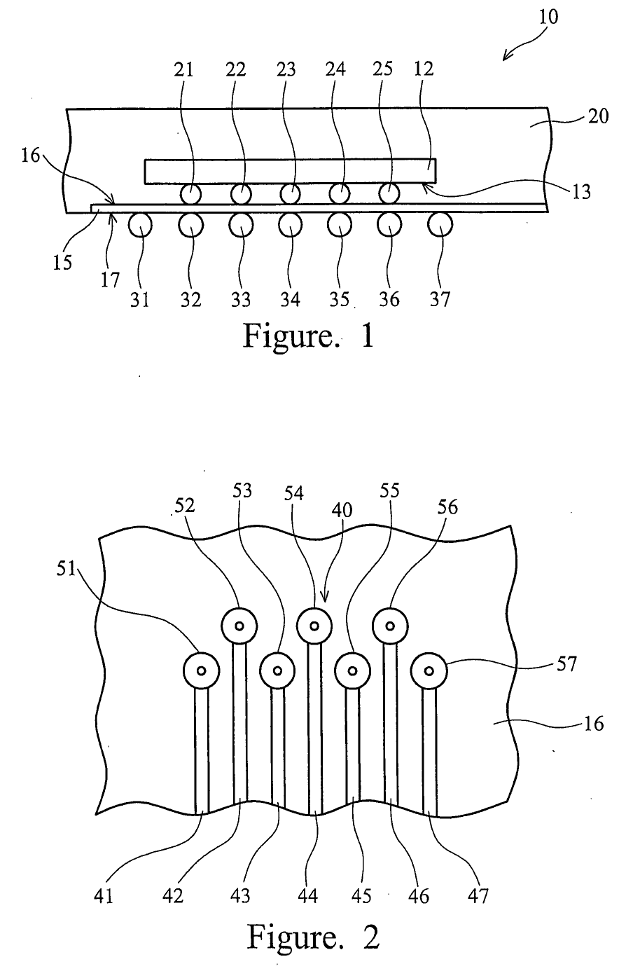

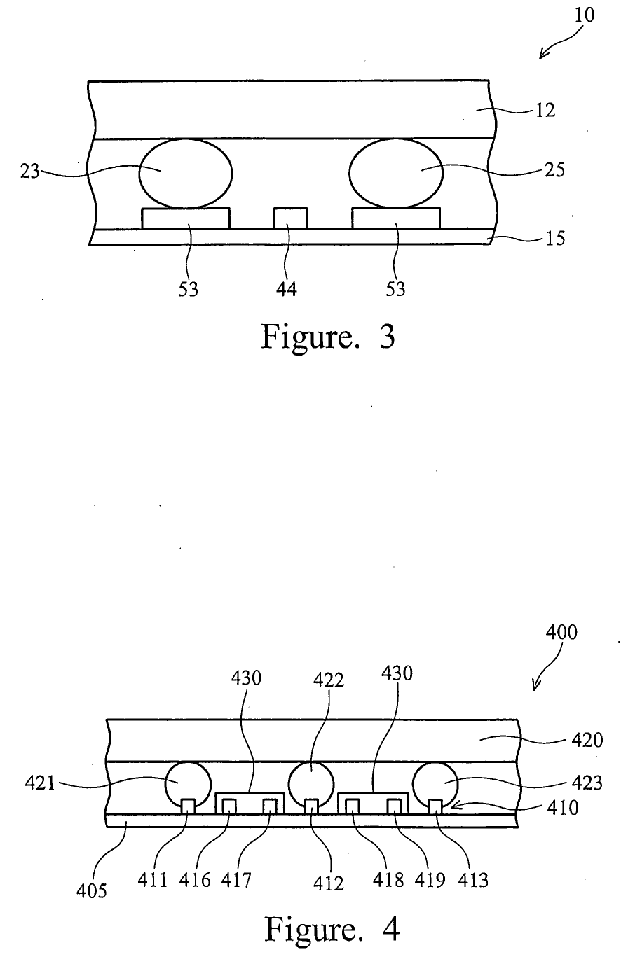

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely, where the active surface of a die is one upon which the electrical components of the device have been fabricated. (Although not typical or shown here, electrical components may be fabricated on other areas of the die as well, creating more than one active surface.) The invention may also be applied, however, to other semiconductor devices as well.

The present invention, then, is directed to a low cost substrate design especially advantageous for use in a flip chip semiconductor device. Traditional designs offer less-than-optimum options for routing traces on the surface of the substrate, especially in designs using small conductive bumps and via dimensions. For example, pads currently used for bump-on-via designs have to be relatively larger, usually greater than 110 mm in diameter, to avoid problems associated with delamination, especially in NSMD (non-solder-mask defined) OSP (organic solderability preservative) applications. The approach of the present invention to solving this problem will now be described in more detail.

FIG. 4 is a side view illustrating in cross-section a portion of a flip chip 400 according to an embodiment of the present invention. Flip chip 400 includes a substrate 405 on the top side of which have been formed a number of electrical traces, which are referred to generally as 410. A die 420 bears a number of circuits and electronic devices, which are coupled both electrically and mechanically to the substrate 405. Specifically conductive bump 421 is directly mounted on trace 411, not on the pad. Structures to either side of conductive bump 421 are protected by adjacent portions of the dielectric layer 430. Note that conductive bump 421 could be mounted using any of several methods, such as by applying an adhesive. In the typical embodiment of the present invention, however, the conductive bump 421 is a eutectic solder ball and a reflow process is used to mount each of the bumps. Note that while only three bumps are shown in FIG. 4, in typical applications there are dozens. The other bumps shown in FIG. 4 are also mounted to traces; conductive bump 422 to trace 412, and conductive bump 423 to trace 413. While each of the bumps in FIG. 4 is attached to a single trace, as is typical, in some applications more than one bump may be mounted on a single trace. And, of course, it is not required that every trace is used to mount a solder ball. Some traces, in fact, may well be used for other purposes, or may not be used at all.

By mounting each bump on a trace as shown in FIG. 4, however, at least two traces may be routed in between bumps, providing greater design flexibility. Traces 416 and 417, for example, may be routed in between conductive bumps 421 and 422, and traces 418 and 419 may be routed between bumps 422 and 423. Note, however, that while this embodiment of the present invention provides space for routing two or more traces, the actual presence of a plurality of traces may not in all applications be necessary or desirable, and is therefore not a requirement of the invention unless explicitly recited or apparent from the context. In the embodiment of FIG. 4, electrical traces are covered with a protective coating, such as a dielectric material 430, at locations where no bump is to be mounted. The use of a dielectric layer 430, however, is not required.

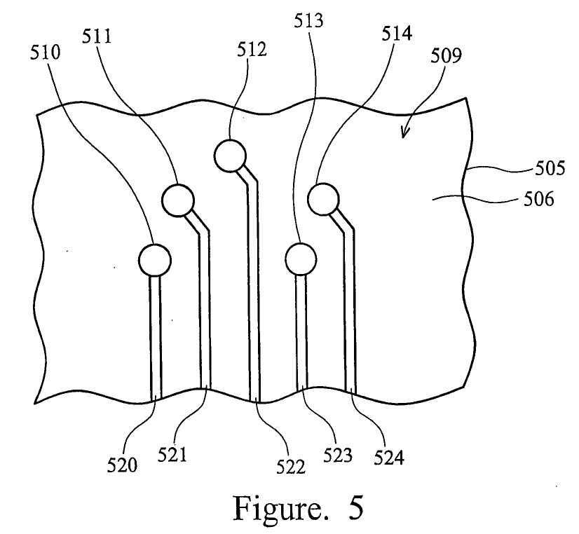

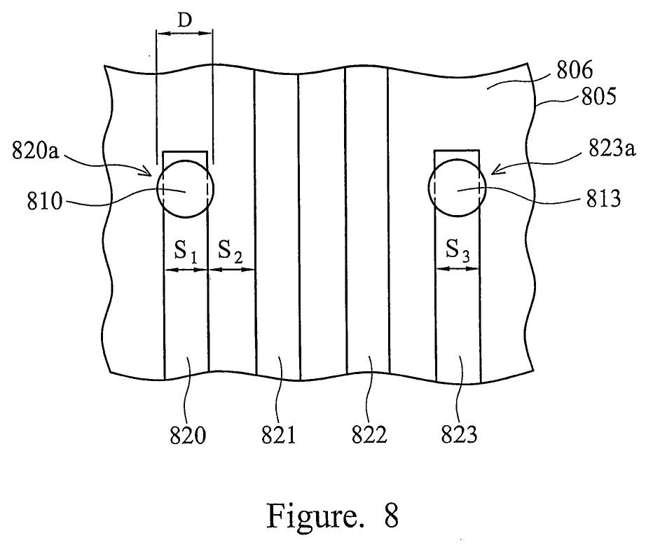

A plan view of a portion of this arrangement may be seen in FIG. 5. FIG. 5 is a plan view illustrating a portion of the trace pattern 509 on the surface 506 of a substrate 505 according to an embodiment of the present invention. In this embodiment, as should be apparent, the conductive bumps are mounted directly onto the traces, instead of on pads over vias as is the case in the prior art. In FIG. 5, conductive bumps 510, 511, 512, 513, and 514 are mounted on traces 520, 521, 522, 523, and 524, respectively. This configuration permits at least two electrical traces to be routed between conductive bumps, for example traces 521 and 522 are able to escape between conductive bumps 510 and 513. Note that FIG. 5 is not necessarily drawn to scale. A particularly preferred embodiment, however, is more clearly illustrated in FIG. 8.

FIG. 8 is a plan view illustrating a partial trace pattern 809 on the surface 806 of a substrate 805 according to an embodiment of the present invention. Note that the embodiment of FIG. 8 is similar to the one shown in FIG. 5, and corresponding features will be numbered analogously. In the embodiment of FIG. 8, solder balls 810 and 813 having diameter D are shown mounted on the respective contact areas 820a and 823a of traces 820 and 823. Traces 821 and 822 are routed between solder balls 810 and 813. Each of the traces 820 through 823 has a width S₁ and is separated from adjacent traces by a space S₂. Contact portions 820a and 823a have a width S₃. In a preferred embodiment, S₁=S₂=S₃ and fall within a range of above 20 mm to about 50 mm. Uniformity in size, however, is not a requirement unless specifically recited. This is true also of the solder balls, although use of solder balls having varying sizes is not typical. In a preferred embodiment, the ratio of trace width S₁ to solder ball diameter D is within the range of about 0.7 to about 1.0.

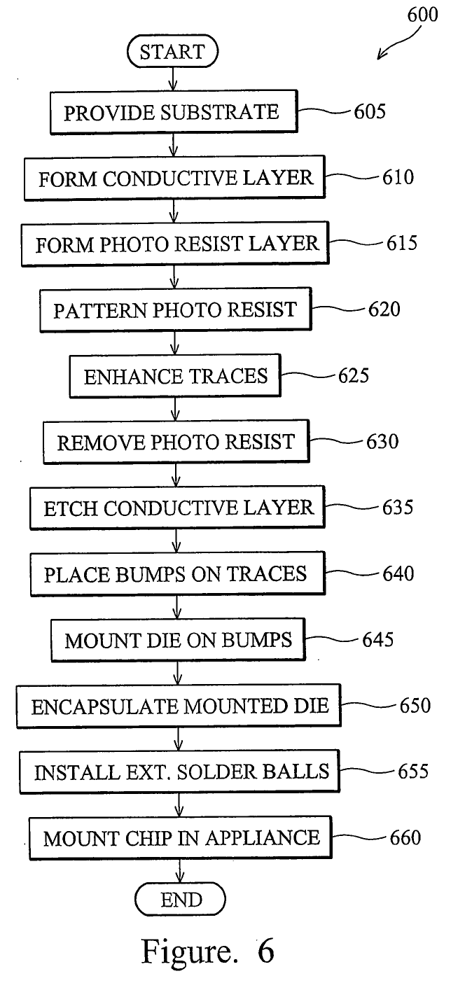

The process of forming the traces according to an embodiment the present invention will now be explained in greater detail with reference to FIG. 6. FIG. 6 is a flow diagram illustrating a method 600 of fabricating a semiconductor device according to an embodiment of the present invention. At START, it is presumed that the materials and equipment necessary to performing the method 600 are available and operational. The method then begins by providing a substrate (step 605). In a preferred embodiment, the substrate is a BT laminate substrate. Although applying the present intervention to this type of substrate is known to in most cases produce an advantage, other types of substrates may be used as well, and no result or level of improvement is required unless recited in a particular claim. It is noted that the fabrication process may not actually begin with the substrate, for example in many instances the integrated circuits are formed on the die at the same time or prior to forming traces on the substrate. In this context, it is also noted that the operations of method 600 may be performed in any logically consistent order unless noted otherwise

In the embodiment of FIG. 6, a thin layer of conductive material for the traces is added to at least one side of the substrate by forming a layer of conductive material over the surface (step 610). The substrate, shown for example in FIGS. 4 and 5 and described above, is typically a thin, flat piece of material having a side that in the assembled semiconductor device faces the die (or dice), and an opposite side that faces toward the printed circuit board or other device to which the chip is attached. For convenience herein, the side facing the die will sometimes be referred to as the die side or interior side of the substrate. Often this relationship will be arbitrary, that is, the substrate material may have either side positioned to face the die. In the embodiment of FIG. 6, the conductive layer is formed on at least the die side of the substrate.

Once the thin conductive layer has been formed, in this embodiment, a photoresist layer is formed (step 615) and patterned (step 620). In this embodiment, the photoresist is patterned in to positions that will not be actual traces, covering a certain portion of the already formed conductive layer. Different types of photoresist may be used in different cases, the only requirement being that it is suitable for the conductive layer etching process. The thickness of the photoresist layer may be in part determined by requirements of the enhancement process, although this is necessarily the case. After the photoresist has been patterned, an enhancement is performed (step 625) to fully form the electrical traces on the face of the substrate.

In accordance with this embodiment of the present invention, therefore, the traces are enhanced (in step 625) by the addition of additional material. In the preferred embodiment, this additional material has the same composition as the material used for the conductive layer. Copper is presently preferred for both purposes. In alternate embodiments (not shown), however, the conductive layer. It may also include more than one layer of material, some of which may not be conductive. In addition, different enhancement materials may be used on different portions of the substrate surface, and the amount of material used may vary by location as well. As should be apparent, however, in those alternate embodiments additional photoresist application and patterning operations, or processes to similar effect, may have to be used to achieve different enhancement patterns. These additional operations are not shown in FIG. 6.

Returning to the embodiment of FIG. 6, once the enhancement operation is complete, the remaining photoresist is removed (step 630) using an appropriate solvent. Note that what remains on the face of the substrate will be a copper layer that is relatively thin in some areas and relatively thick in others. An etch is now performed (step 635) for a limited period of time. That is, the etch used should leave the enhanced portions in place so that they can function as electrical traces, while eliminating the un-enhanced portions in between. As should be apparent, the goal of the etch is to degrade the traces as little as possible while ensuring that the undesired copper between them is removed.

Other methods of enhancement may be used. In one alternate embodiment (not shown), the photoresist is patterned to leave exposed the areas of the conductive layer that lie in between the traces, which are then removed by etching. The traces may then simply be used as is, but are preferably enhanced with additional conductive material after the photoresist is removed. Electroplating may be used, for example, to add additional conductive material to the traces but leave clear the areas in between. A limited etch may be added in this case to remove any material that does adhere to unwanted areas.

Returning to the method of FIG. 6, once the traces have been enhanced and the remaining photoresist (or other such material) removed, the conductive bumps may be placed on the appropriate trace (step 640). In a preferred embodiment, the conductive bumps are eutectic solder balls. A die to which the conductive bumps will establish a connection is then put into place (step 645) and the assembly heated to flow the solder or other bump material into a form where it securely mounts the die and substrate together. In an alternate embodiment (not shown), the conductive bump flow occurs prior to placing the die, in which can another, similar if not identical operation is performed to secure the die to the mounted bumps. In any event, the die and substrate assembly is then encapsulated (step 650) and solder balls mounted to the outside of the substrate (step 655). The completed flip chip may then be mounted (step 660) on a circuit board or similar structure for the appliance in which the device is to be used. Finally, note that the steps of method 600 may be performed in any logical order within the spirit of the present invention.

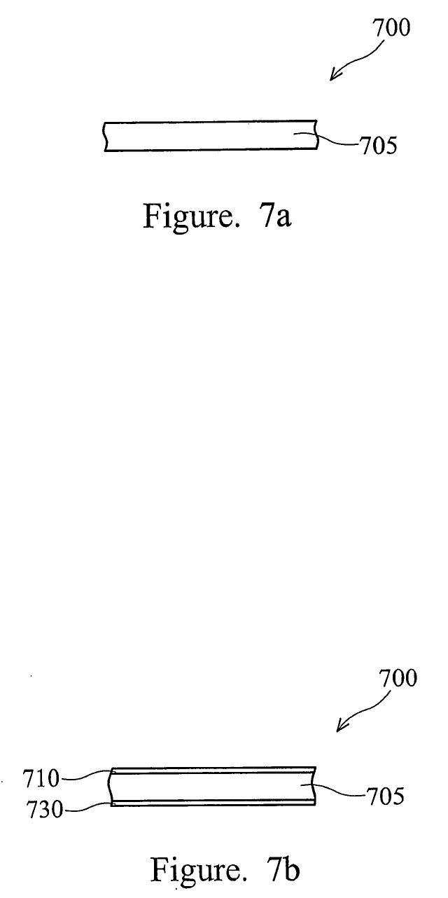

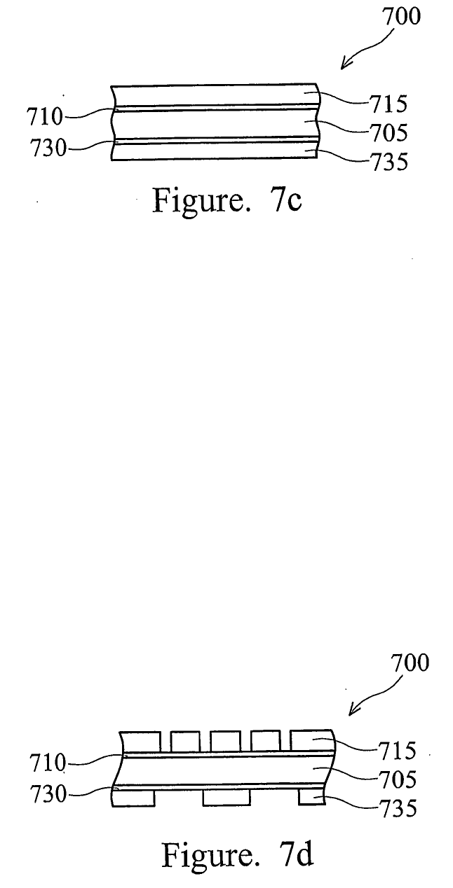

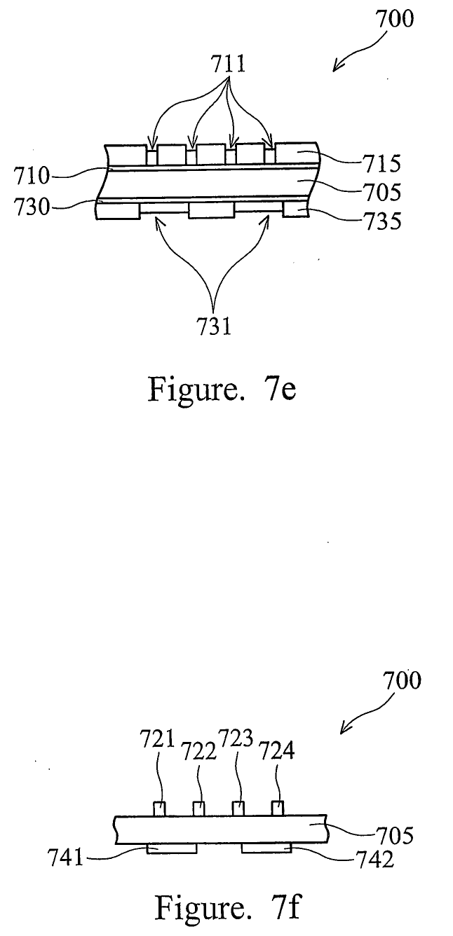

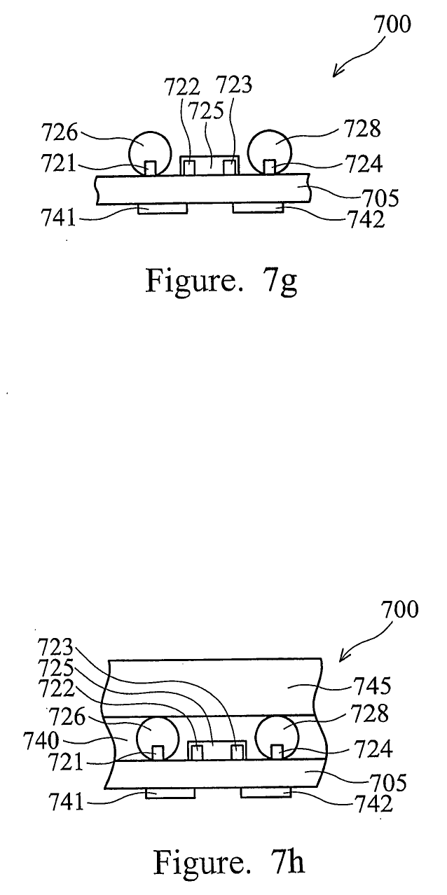

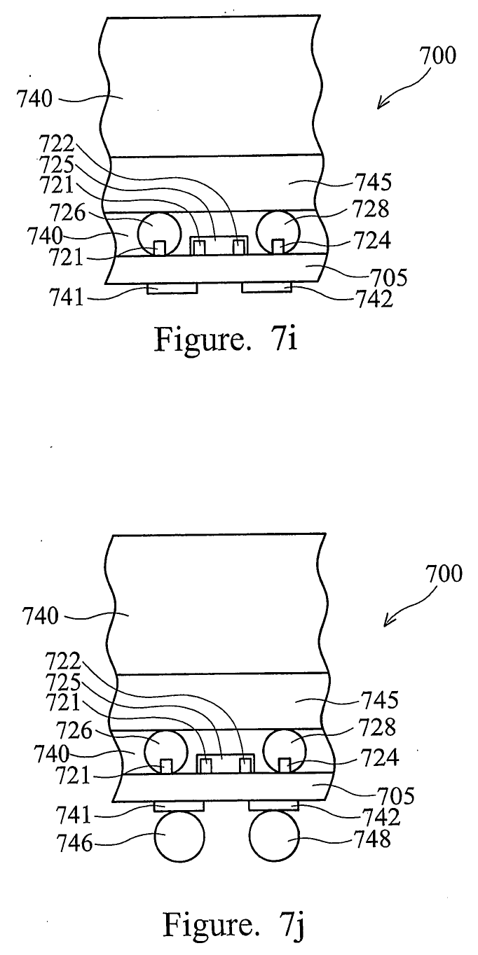

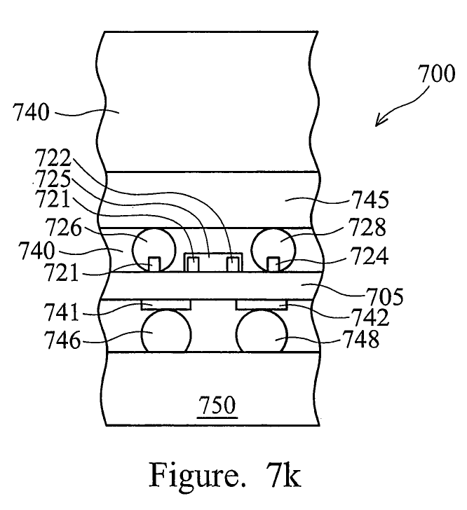

FIG. 7a through 7k are a sequence of side views illustrating in cross section the configuration of a semiconductor device 700 during fabrication according to a method of the present invention. A substrate portion 705 is shown in FIG. 7a. Again this sequential via of fabrication shows first the substrate for convenience, even though other component parts of the semiconductor device may at this stage be in manufacture or have already been manufactured. Onto the substrate are formed a die-side, in this embodiment top, conductive layer 710 and a bottom conductive layer 730. As shown in FIG. 7b, these are uniform but relatively thin layers. A top photoresist layer 715 a bottom photoresist layer 735 are then formed, as shown in FIG. 7.

Each photoresist layer is then patterned resulting in the configuration represented in FIG. 7d. In this embodiment, the top side is being prepared with electrical traces for receiving the conductive bumps, which will in turn attach the substrate to the die. The bottom of the substrate will be used to mount bumps for mounting the semiconductor device 700 to a printed circuit board. In the embodiment of FIGS. 7a through 7k, a conductive layer enhancement is then performed, with additional conductive material be added to the exposed portions of conductive layers 710 and 730, as shown in FIG. 7e. Note that in FIG. 7e, the enhanced portions 731 of bottom conductive layer 730 are shown as separate structures for the purposes of illustration. In actual fabrication, in most applications it is preferred that the conductive layer and the respective enhanced portions 731 are of the same material, such as copper, and following enhancement simply form a continuous structure.

In this embodiment, the remaining photoresist layers 715 and 735 are then removed, leaving the enhanced conductive layers on either side of the substrate. The conductive material in between the desired structures is then removed by an etching process. In this embodiment a wet etch is preferred. When completed, the undesired conductive material is removed, resulting in the configuration illustrated in FIG. 7f. As should be apparent. The enhanced portions 711 and 731 (shown in FIG. 7e are also degraded in the etching process, but the remaining structures represent an enhanced portion of the previously-deposited conductive layers. In FIG. 7f, the structures on the die side 706 of substrate portion 705 are electrical traces 721 through 724. On the exterior side 708, the structures are bond pads 741 and 742. This is for illustration, of course; other structures may, and usually are formed in a similar manner as well.

Note that in this embodiment, the exposed portions of the original conductive layers act as a seed layer for the deposition of additional conductive material. Electroplating is preferably used so that the additional conductive material is deposited only on the exposed conductive layer portions. Alternatively, an entire layer of conductive material (not shown) may be added and, if necessary, planarized by an additional etching or a CMP step. And while it is more efficient in most applications to form structured on both sides of the substrate portion 705 at the same time, they may in some cases be fabricated separately as well. Note that vias filled with conductive material, bond wires, or similar structures may be used to provide the necessary electrical connections between structures formed on the interior side of substrate portion 705 and those formed on the exterior 708. For simplicity, these connecting structures are not shown.

Returning to the embodiment of FIGS. 7a through 7k after the traces have been enhanced and any remaining photoresist removed, the conductive bumps are then placed appropriately and, in this embodiment, flowed into secure mounting on the substrate traces, as shown in FIG. 7g. Here, only conductive bump 726 and conductive bump 728 are shown, mounted on electrical traces 721 and 724, respectively. The electrical traces 722 and 723 are shown here protected by a dielectric layer 725, though at other points along their length they may be exposed and have additional conductive bumps (not shown) mounted on them as well. The die may then be mounted in similar fashion to the conductive bumps. Note in some applications, more than one die will be installed. Additional die may either be mounted beside the die or stacked and connected to the substrate by bond wires or similar technology. For simplicity, only a single die 745 is shown in FIG. 7h. The conductive bumps 726 and 728 are often mounted to a bond pad on the die itself, but the details of this mounting are not shown here.

The assembly is then encapsulated using a suitable encapsulant material 740 forming a package, as shown in FIG. 7i. In this embodiment, which of course represents only a small (but representative) portion of semiconductor device 700, the encapsulant 740 is used to fill the remaining gap between substrate portion 705 and die 745, as well as to encase the entire structure. This simplified representation omits other encapsulated structures and multiple layers of encapsulant or other housing materials that may present. The semiconductor device 700 may now be mounted. FIG. 7j is a representation of semiconductor device after solder balls or other conductive bumps have been mounted to the encapsulated assembly. Solder balls 746 and 748 are shown here, mounted respectively to bond pads 741 and 742, though again in the entire device there will be many more mounted in similar fashion. Finally, FIG. 7k illustrates the completed semiconductor device 700, in this embodiment a flip chip, mounted to a printed circuit board 750. This mounting is exemplary, of course, and other mounting configurations are possible.

Although the present invention and its advantages have been described in detail, it should be understood that various changes, substitutions and alterations can be made herein without departing from the spirit and scope of the invention as defined by the appended claims. For example, many of the features and functions discussed above can be implemented using other materials than those described above. As another example, it will be readily understood by those skilled in the art that other materials and final assembly details may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device, comprising:
a substrate having a die side and an exterior side;
a first conductive layer formed on the die side of the substrate; wherein the first conductive layer is patterned to form a plurality of traces; and
a plurality of conductive bumps, wherein each conductive bump is mounted on one trace of a plurality of the traces and is positioned a minimum dimension from each other bump of the plurality of conductive bumps, the minimum dimension being sufficient for a routing of two separate traces therethrough;
a first die, said first die comprising one or more integrated circuits selectively coupled to at least a first portion of the plurality of conductive bumps, wherein the first die is mounted on the die side of the substrate;
a second die, said second die comprising one or more integrated circuits selectively coupled to at least a second portion of the plurality of conductive bumps, wherein the second die is mounted on the die side of the substrate.

2. The semiconductor device of claim 1, wherein the plurality of conductive bumps comprise solder balls.

3. The semiconductor device of claim 1, wherein the first conductive layer comprises copper.

4. The semiconductor device of claim 1, wherein the substrate is a BT laminate substrate.

5. The semiconductor device of claim 1, further comprising a second conductive layer formed on the exterior side of the substrate.

6.-7. (canceled)

8. The semiconductor device of claim , further comprising a plurality of external bumps coupled to the second conductive layer for mounting the semiconductor device within an electronic appliance.

9. A method of fabricating a semiconductor device, comprising:
providing a first conductive layer forming a plurality of traces on a first side of a substrate;
enhancing at least a portion of the plurality of traces with additional conductive material; and
mounting a plurality of conductive bumps, each bump being mounted to a trace of the plurality of traces;
wherein each conductive bump is positioned a minimum dimension from each other bump of the plurality of bumps, the minimum dimension being sufficient for the routing of two separate traces therethrough.

10. The method of fabricating a semiconductor device of claim 9, further comprising mounting a die on the plurality of conductive bumps.

11. The method of fabricating a semiconductor device of claim 10, further comprising:
providing a second conductive layer on a second side of the substrate; and
patterning the second conductive layer.

12. The method of claim 11, further comprising forming vias containing conductive material to provide an electrical connection between elements of the first conductive layer and elements of the second conductive layer.

13. The method of fabricating a semiconductor device of claim 11, further comprising mounting a plurality of conductive bumps on the second side of the substrate, each conductive bump coupled to an element of the second conductive layer.

14. The method of fabrication a semiconductor device of claim 9, wherein providing the first conductive layer is performed using a surface treatment process.

15. The method of fabricating a semiconductor device of claim 9, wherein forming the plurality of traces comprises forming a photoresist layer, patterning the photoresist layer, and selectively etching the first conductive layer.

16. The method of fabricating a semiconductor device of claim 15, wherein the etch of the first conductive layer is a wet etch.

17. The method of fabricating a semiconductor device of claim 15, where in the trace enhancement is performed prior to etching the first conductive layer.

18. The method of fabricating a semiconductor device of claim 17, wherein the enhancement is performed using electroplating.

19. A semiconductor device, comprising:
a substrate having a plurality of traces on at least an upper surface;
a plurality of semiconductor die disposed on the upper surface in a spaced-apart relationship; and
a plurality of conductive bumps, each bump mounted so as to electrically connect a feature on the plurality of semiconductor die with a trace on the upper surface of the substrate;
and wherein a ratio of a width of any trace relative to a diameter of a bump mounted on it is within the range of about 0.7 to about 1.0.
